(19) United States
(12) Patent Application Publication
(10) Pub. No.: US 2023/0061742 A1
(43) Pub. Date: Mar. 2, 2023

(54) METHOD FOR LIGHT-EMITTING ELEMENT TRANSFERRING AND DISPLAY PANEL

(71) Applicant: CHONGQING KONKA PHOTOELECTRIC TECHNOLOGY RESEARCH INSTITUTE CO., LTD., Chongqing (CN)

(72) Inventors: Fei PAN, Chongqing (CN); CHENG-MING LIU, Chongqing (CN)

(21) Appl. No.: 17/881,033

(22) Filed: Aug. 4, 2022

Related U.S. Application Data
(63) Continuation of application No. PCT/CN2021/114854, filed on Aug. 26, 2021.

(51) Int. Cl. H01L 33/08; H01L 25/075; H01L 23/00; H01L 33/00; H01L 33/60; H01L 27/15; H01L 33/62; H01L 25/065

(52) U.S. Cl. CPC H01L 33/08; H01L 25/0753; H01L 24/95; H01L 33/0093; H01L 33/60; H01L 27/15; H01L 33/62; H01L 24/16; H01L 24/14; H01L 24/05; H01L 24/06; H01L 24/08; H01L 25/0655; H01L 2224/05573; H01L 2224/06181; H01L 2224/08237; H01L 2224/95136; H01L 2924/12041; H01L 2224/1403; H01L 2224/14181; H01L 2224/16237; H01L 2924/15153; H01L 2924/15156

(57) ABSTRACT

A method for light-emitting element transferring includes: providing multiple light-emitting elements, each light-emitting element includes a first light-emitting unit, a substrate, and a second light-emitting unit sequentially stacked, the first light-emitting unit includes a first epitaxial structure and a first electrode group stacked on a side of the substrate, the second light-emitting unit includes a second epitaxial structure and a second electrode group stacked on another side of the substrate, and the first light-emitting unit and the second light-emitting unit have different light-emitting colors; providing a display backplane, multiple grooves are defined on the display backplane, a first pad group and a second pad group are provided on side walls of each groove; and embedding the multiple light-emitting elements into the multiple grooves in one-to-one correspondence, where the first electrode group is bonded with the first pad group, and the second electrode group is bonded with the second pad group.

### CROSS-REFERENCE TO RELATED APPLICATION(S)

This application is a continuation of International Application No. PCT/CN2021/114854, filed Aug. 26, 2021, the disclosure of which is hereby incorporated by reference in its entirety.

### TECHNICAL FIELD

This disclosure relates to the field of semiconductor light-emitting technology, and in particular, to a method for light-emitting element transferring and a display panel.

### BACKGROUND

Light-emitting diodes (LED) have been widely used in many lighting display fields because of their excellent characteristics such as high light-emitting efficiency, high reliability, and flexible assembly size, especially in outdoor large billboards, stage background walls, large text broadcast screens, and other large-sized display application scenarios. At present, a next development trend of LED display is to miniaturize LED chiplets to have a micron size (e.g., micro-LEDs), so that an LED display can replace the existing liquid crystal display (LCD) and the existing organic light-emitting diode (OLED) display in indoor televisions (TV), phone display, wearable devices, and other medium and small-sized display application scenarios that are occupied by the LCD and the OLED display.

Implementation of the existing micro-LED based full-color display is mainly based on a mass transfer technology of micro-LED chips. First, red color micro-LED epitaxy, green color micro-LED epitaxy, and blue color micro-LED epitaxy (“RGB micro-LED epitaxy” for short) are grown, and red color micro-LED chips, green color micro-LED chips, and blue color micro-LED chips (“RGB micro-LED chips” for short) are generated after a chip manufacturing process. Then mass transfer is performed on the RGB micro-LED chips respectively to achieve full-color display. However, for micro-LED chips of micron sizes, the mass transfer is more difficult to implement. At present, the mass transfer for the RGB chips needs to be performed at least three times, and moreover, a yield and efficiency of the mass transfer cannot satisfy a mass production demand.

### SUMMARY

In a first aspect, a method for light-emitting element transferring is provided. The method for light-emitting element transferring includes the following. Multiple light-emitting elements are provided, where each of the multiple light-emitting elements includes a substrate, a first light-emitting unit disposed on a first side of the substrate, and a second light-emitting unit disposed on a second side of the substrate. The first side of the substrate is opposite to the second side of the substrate. The first light-emitting unit includes a first epitaxial structure and a first electrode group that are sequentially stacked on the first side of the substrate. The second light-emitting unit includes a second epitaxial structure and a second electrode group that are sequentially stacked on the second side of the substrate. A light-emitting color of the first light-emitting unit is different from that of the second light-emitting unit. A display backplane is provided, where multiple grooves are defined on a side of the display backplane, and a first pad group and a second pad group are provided on side walls of each of the multiple grooves. The multiple light-emitting elements are embedded into the multiple grooves in one-to-one correspondence, where the first electrode group is bonded with the first pad group, and the second electrode group is bonded with the second pad group.

In a second aspect, a display panel is further provided. The display panel includes a display backplane and multiple pixel units fixed on the display backplane. Each of the multiple pixel units includes two light-emitting elements spaced apart from one another, and the light-emitting element is fixed onto the display backplane by embedding light-emitting elements of the multiple pixel units into multiple grooves in one-to-one correspondence. Each of the light-emitting elements includes a substrate, a first light-emitting unit disposed on a first side of the substrate, and a second light-emitting unit disposed on a second side of the substrate. The first side of the substrate is opposite to the second side of the substrate. The first light-emitting unit includes a first epitaxial structure and a first electrode group that are sequentially stacked on the first side of the substrate. The second light-emitting unit includes a second epitaxial structure and a second electrode group that are sequentially stacked on the second side of the substrate. A light-emitting color of the first light-emitting unit is different from that of the second light-emitting unit. The multiple grooves are defined on a side of the display backplane, and a first pad group and a second pad group are provided on side walls of each of the multiple grooves. The first electrode group is bonded with the first pad group, and the second electrode group is bonded with the second pad group.

### BRIEF DESCRIPTION OF THE DRAWINGS

FIG. 1 is a flow chart illustrating a method for light-emitting element transferring provided in an implementation of the disclosure.

FIG. 2 is a schematic cross-sectional diagram illustrating a light-emitting element provided in an implementation of the disclosure.

FIG. 3 is a schematic cross-sectional diagram illustrating a display backplane provided in an implementation of the disclosure.

FIG. 4 is a schematic cross-sectional diagram illustrating a light-emitting element and a display backplane after the light-emitting element is embedded into the display backplane provided in an implementation of the disclosure.

FIG. 5 is a schematic cross-sectional diagram illustrating a light-emitting element provided in another implementation of the disclosure.

FIG. 6 is a schematic cross-sectional diagram illustrating a display backplane provided in another implementation of the disclosure.

FIG. 7 is a schematic cross-sectional diagram illustrating a light-emitting element and a display backplane after the light-emitting element is embedded into the display backplane provided in another implementation of the disclosure.

FIG. 8 is a schematic cross-sectional diagram illustrating a display backplane provided in yet another implementation of the disclosure.

FIG. 9 is a schematic cross-sectional diagram illustrating a light-emitting element and a display backplane after the light-emitting element is embedded into the display backplane provided in yet another implementation of the disclosure.

FIG. 10 is a flow chart illustrating a manufacturing method of a light-emitting element provided in an implementation of the disclosure.

FIG. 11 is a schematic cross-sectional diagram illustrating a light-emitting element obtained after operations at S1011 in FIG. 10 are completed.

FIG. 12 is a schematic cross-sectional diagram illustrating a light-emitting element obtained after operations at S1012 in FIG. 10 are completed.

FIG. 13 is a schematic cross-sectional diagram illustrating a light-emitting element obtained after operations at S1013 in FIG. 10 are completed.

FIG. 14 is a schematic cross-sectional diagram illustrating a light-emitting element obtained after operations at S1014 in FIG. 10 are completed.

FIG. 15 is a schematic cross-sectional diagram illustrating a light-emitting element obtained after operations at S1015 in FIG. 10 are completed.

FIG. 16 is a schematic cross-sectional diagram illustrating a light-emitting element obtained after operations at S1016 in FIG. 10 are completed.

FIG. 17 is a flow chart illustrating a manufacturing method of a light-emitting element provided in another implementation of the disclosure.

FIG. 18 is a schematic cross-sectional diagram illustrating a light-emitting element obtained after operations at S1017 in FIG. 17 are completed.

FIG. 19 is a schematic cross-sectional diagram illustrating a light-emitting element obtained after operations at S1018 in FIG. 17 are completed.

FIG. 20 is a schematic cross-sectional diagram illustrating a light-emitting element obtained after operations at S1019 in FIG. 17 are completed.

FIG. 21 is a schematic cross-sectional diagram illustrating a light-emitting element obtained after operations at S1020 in FIG. 17 are completed.

FIG. 22 is a top view illustrating a display panel provided in an implementation of the disclosure.

FIG. 23 is a side view illustrating a display panel provided in an implementation of the disclosure.

Description of reference signs of the accompanying drawings: 100—light-emitting element; 10—substrate; 11—first substrate; 12—second substrate; 20—first light-emitting unit; 21—first epitaxial structure; 22—first electrode group; 221—first sub-electrode; 222—second sub-electrode; 30—second light-emitting unit; 31—second epitaxial structure; 32—second electrode group; 321—third sub-electrode; 322—fourth sub-electrode; 200—display backplane; 50—groove; 501—first groove; 502—second groove; 60—first pad group; 61—first sub-pad; 62—second sub-pad; 70—second pad group; 71—third sub-pad; 72—fourth sub-pad; 300—display panel; 110—pixel unit; 120—encapsulation layer; 130—blackening layer; 140—reflective layer; 150—first bonding layer; 160—second bonding layer.

### DETAILED DESCRIPTION

In order to facilitate understanding of the disclosure, a detailed description will be given with reference to relevant accompanying drawings. The accompanying drawings illustrate some exemplary implementations of the disclosure. However, the disclosure can be implemented in many different forms and is not limited to the implementations described herein. On the contrary, these implementations are provided for a more thorough and comprehensive understanding of the disclosure.

Unless otherwise defined, all technical and scientific terms used herein have the same meaning as commonly understood by those skilled in the art of the disclosure. The terms used herein in the disclosure are for the purpose of describing implementations only and are not intended to limit the disclosure.

The terms “first”, “second”, and the like used in the specification of the disclosure are used to distinguish different objects rather than describe a particular order. In addition, locations or positional relationships indicated by terms such as “on”, “under”, “in”, “out”, and the like are locations or positional relationships based on accompanying drawings and are only for the convenience of description and to simplify the description, rather than explicitly or implicitly indicate that apparatuses or components referred to herein must have a certain location or be configured or operated in a certain location and therefore cannot be understood as limitation on the disclosure.

It should be noted that the drawings provided in implementations of the disclosure illustrate the basic concept of the disclosure only in a schematic way, and only the components related to the disclosure are illustrated in the drawings, instead of being drawn according to the number, shapes, and sizes of the components in actual implementations. The types, number, and proportions of each component in actual implementations can be arbitrarily changed, and the layout of the components may be more complicated.

At present, the mass transfer technology includes performing mass transfer on the RGB micro-LED chips respectively to achieve full-color display, the mass transfer for the RGB chips, however, needs to be performed at least three times, and moreover, a yield and efficiency of the mass transfer cannot satisfy a mass production demand.

In view of the above deficiencies of the related art, the disclosure provides a method for light-emitting element transferring and a display panel. By transferring light-emitting elements capable of emitting dual-color lights, full-color display can be realized through only two times of mass transfer, thereby reducing the number of times of mass transfer and improving efficiency and a yield of mass transfer.

A method for light-emitting element transferring is provided. The method for light-emitting element transferring includes the following. Multiple light-emitting elements are provided, where each of the multiple light-emitting elements includes a substrate, a first light-emitting unit disposed on a first side of the substrate, and a second light-emitting unit disposed on a second side of the substrate. The first side of the substrate is opposite to the second side of the substrate. The first light-emitting unit includes a first epitaxial structure and a first electrode group that are sequentially stacked on the first side of the substrate. The second light-emitting unit includes a second epitaxial structure and a second electrode group that are sequentially stacked on the second side of the substrate. A light-emitting color of the first light-emitting unit is different from that of the second light-emitting unit. A display backplane is provided, where multiple grooves are defined on a side of the display backplane, and a first pad group and a second pad group are provided on side walls of each of the multiple grooves. The multiple light-emitting elements are embedded into the multiple grooves in one-to-one correspondence, where the first electrode group is bonded with the first pad group, and the second electrode group is bonded with the second pad group.

In an implementation, the first electrode group includes a first sub-electrode and a second sub-electrode spaced apart from one another. The second electrode group includes a third sub-electrode and a fourth sub-electrode spaced apart from one another. The first sub-electrode projects from a side of the second sub-electrode away from the substrate, and the third sub-electrode projects from a side of the fourth sub-electrode away from the substrate. By setting the first sub-electrode to project from the side of the second sub-electrode away from the substrate and setting the third sub-electrode to project from the side of the fourth sub-electrode away from the substrate, the first sub-electrode and the second sub-electrode of the light-emitting element are arranged in a stepped manner, and the third sub-electrode and the fourth sub-electrode of the light-emitting element are arranged in a stepped manner, which is conducive to alignment of the light-emitting element and the display backplane during transferring, so that transfer accuracy can be improved.

In an implementation, the first pad group includes a first sub-pad and a second sub-pad. The second pad group includes a third sub-pad and a fourth sub-pad. The first sub-pad is disposed opposite to the third sub-pad, and the second sub-pad is disposed opposite to the fourth sub-pad. A gap spaced by the first sub-pad and the third sub-pad is greater than a gap spaced by the second sub-pad and the fourth sub-pad. On condition that the light-emitting element is embedded into the groove, the first sub-electrode is bonded with the first sub-pad, the second sub-electrode is bonded with the second sub-pad, the third sub-electrode is bonded with the third sub-pad, and the fourth sub-electrode is bonded with the fourth sub-pad. By setting the gap spaced by the first sub-pad and the third sub-pad to be greater than the gap spaced by the second sub-pad and the fourth sub-pad, the second sub-pad projects from the first sub-pad and the second sub-pad and the first sub-pad are arranged in a stepped manner, the fourth sub-pad projects from the third sub-pad and the fourth sub-pad and the third sub-pad are arranged in a stepped manner. As such, when the stepped light-emitting element is transferred onto the display backplane, the light-emitting element can be accurately embedded into the groove, which is conducive to aligning and bonding the electrode groups of the light-emitting element with the pad groups.

In an implementation, the groove includes a first groove and a second groove that are sequentially stacked on the display backplane and stacked in a stepped manner. The first groove has an opening area less than the second groove. The first sub-pad and the third sub-pad are disposed on side walls of the second groove. The second sub-pad and the fourth sub-pad are disposed on side walls of the first groove. By setting the groove to be stepped, it is conducive to accurately embedding the stepped light-emitting element into the groove.

In an implementation, the multiple light-emitting elements are provided as follows. A first substrate and the first epitaxial structure that are stacked are provided. A second substrate and the second epitaxial structure that are stacked are provided. An end of the second epitaxial structure away from the second substrate is bonded with an end of the first substrate away from the first epitaxial structure. The second substrate is removed. The first electrode group is formed on a side of the first epitaxial structure away from the first substrate. The second electrode group is formed on a side of the second epitaxial structure away from the first substrate. Alternatively, the multiple light-emitting elements are provided as follows. The first epitaxial structure is formed on the first side of the substrate. The first electrode group is formed on a side of the first epitaxial structure away from the substrate. The second epitaxial structure is formed on the second side of the substrate. The second electrode group is formed on a side of the second epitaxial structure away from the substrate. By forming the light-emitting element capable of emitting dual-color lights, tri-color transfer can be realized through only two times of transferring, so that the number of times of the transferring can be reduced, and efficiency and a yield of transferring can be improved.

In an implementation, the multiple light-emitting elements are provided as follows. The first epitaxial structure is formed on the first side of the substrate. The first electrode group is formed on a side of the first epitaxial structure away from the substrate. The second epitaxial structure is formed on the second side of the substrate. The second electrode group is formed on a side of the second epitaxial structure away from the substrate.

Based on the same inventive concept, the disclosure further provides a display panel. The display panel includes a display backplane and multiple pixel units fixed on the display backplane. Each of the multiple pixel units includes two light-emitting elements spaced apart from one another, and the light-emitting element is fixed onto the display backplane by embedding light-emitting elements of the multiple pixel units into multiple grooves in one-to-one correspondence. Each of the light-emitting elements includes a substrate, a first light-emitting unit disposed on a first side of the substrate, and a second light-emitting unit disposed on a second side of the substrate. The first side of the substrate is opposite to the second side of the substrate. The first light-emitting unit includes a first epitaxial structure and a first electrode group that are sequentially stacked on the first side of the substrate. The second light-emitting unit includes a second epitaxial structure and a second electrode group that are sequentially stacked on the second side of the substrate. A light-emitting color of the first light-emitting unit is different from that of the second light-emitting unit. The multiple grooves are defined on a side of the display backplane, and a first pad group and a second pad group are provided on side walls of each of the multiple grooves. The first electrode group is bonded with the first pad group, and the second electrode group is bonded with the second pad group.

In an implementation, the two light-emitting elements in each of the multiple pixel units are a first light-emitting element and a second light-emitting element. The first light-emitting element is configured to emit a red light and a blue light. The second light-emitting element is configured to emit a red light and a green light. By setting in each of the multiple pixel units the two light-emitting elements each capable of emitting a red light, a problem of low light-emitting efficiency of the red light can be solved, thereby significantly improving brightness of the display panel.

In an implementation, the display panel further includes an encapsulation layer, where the encapsulation layer is filled in a gap spaced by the groove and the light-emitting element and covered on the light-emitting element. By providing the encapsulation layer, the light-emitting element can be further fixed on the display backplane and can be protected from being scratched.

In an implementation, the display panel further includes a blackening layer, where the blackening layer is covered on a region of the display backplane other than the multiple grooves. By providing the blackening layer, a blackening effect of the display panel can be improved, and contrast of the display panel can be improved by reducing reflection of ambient lights.

In an implementation, the display panel further includes a reflective layer stacked on walls of the groove, where the reflective layer is disposed between the walls of the groove and the light-emitting element, and the reflective layer is configured to reflect a light, which is emitted to the groove from the light-emitting element, to an opening of the groove. The reflective layer is provided, which can effectively improve light utilization efficiency, and prevent color impurity of a displayed image caused by cross color due to a light, which is emitted from a side surface of the light-emitting element, entering an adjacent light-emitting element.

In an implementation, the display panel further includes a first bonding layer and a second bonding layer. The first bonding layer is disposed between the first electrode group and the first pad group to bond the first electrode group with the first pad group. The second bonding layer is disposed between the second electrode group and the second pad group to bond the second electrode group with the second pad group.

In an implementation, the encapsulation layer has a thickness greater than or equal to 100 μm, and the thickness of the encapsulation layer is a size of the encapsulation layer in a direction perpendicular to the display backplane.

In an implementation, the first electrode group includes a first sub-electrode and a second sub-electrode spaced apart from one another. The second electrode group includes a third sub-electrode and a fourth sub-electrode spaced apart from one another. The first sub-electrode projects from a side of the second sub-electrode away from the substrate, and the third sub-electrode projects from a side of the fourth sub-electrode away from the substrate.

In an implementation, the first pad group includes a first sub-pad and a second sub-pad. The second pad group includes a third sub-pad and a fourth sub-pad. The first sub-pad is disposed opposite to the third sub-pad, and the second sub-pad is disposed opposite to the fourth sub-pad. A gap spaced by the first sub-pad and the third sub-pad is greater than a gap spaced by the second sub-pad and the fourth sub-pad. On condition that the light-emitting element is embedded into the groove, the first sub-electrode is bonded with the first sub-pad, the second sub-electrode is bonded with the second sub-pad, the third sub-electrode is bonded with the third sub-pad, and the fourth sub-electrode is bonded with the fourth sub-pad.

In an implementation, the groove includes a first groove and a second groove that are sequentially stacked on the display backplane and stacked in a stepped manner. The first groove has an opening area less than the second groove. The first sub-pad and the third sub-pad are disposed on side walls of the second groove. The second sub-pad and the fourth sub-pad are disposed on side walls of the first groove.

In an implementation, the light-emitting element is provided as follows. A first substrate and the first epitaxial structure that are stacked are provided. A second substrate and the second epitaxial structure that are stacked are provided. An end of the second epitaxial structure away from the second substrate is bonded with an end of the first substrate away from the first epitaxial structure. The second substrate is removed. The first electrode group is formed on a side of the first epitaxial structure away from the first substrate. The second electrode group is formed on a side of the second epitaxial structure away from the first substrate.

In an implementation, the light-emitting element is provided as follows. The first epitaxial structure is formed on the first side of the substrate. The first electrode group is formed on a side of the first epitaxial structure away from the substrate. The second epitaxial structure is formed on the second side of the substrate. The second electrode group is formed on a side of the second epitaxial structure away from the substrate.

In an implementation, the second substrate and the second epitaxial structure are provided as follows. The second substrate is provided. A sacrificial layer is formed on the second substrate. The second epitaxial structure is formed on a side of the sacrificial layer away from the second substrate.

According to the above method for light-emitting element transferring, by transferring the light-emitting element capable of emitting dual-color lights onto the display backplane, full-color display can be realized through only two times of transferring of the light-emitting elements, so that the number of times of the transferring can be reduced, and efficiency and a yield of transferring can be improved.

The pixel unit of the above display panel includes the light-emitting elements capable of emitting dual-color lights, and the display panel can realize full-color display through only two times of transferring of the light-emitting elements, so that the number of times of the transferring can be reduced, production efficiency of the display panel can be improved, and a production cost of the display panel can be reduced.

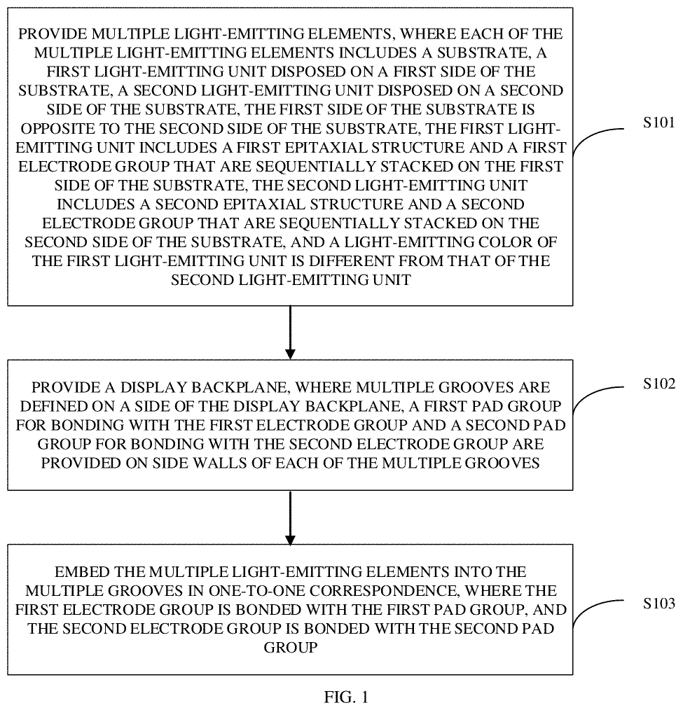

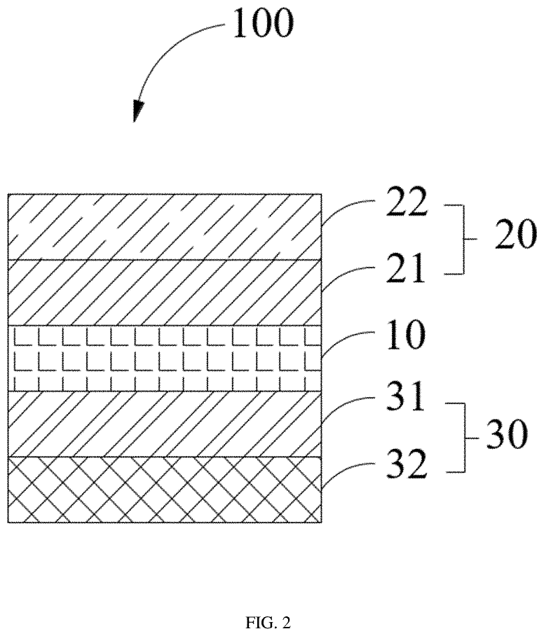

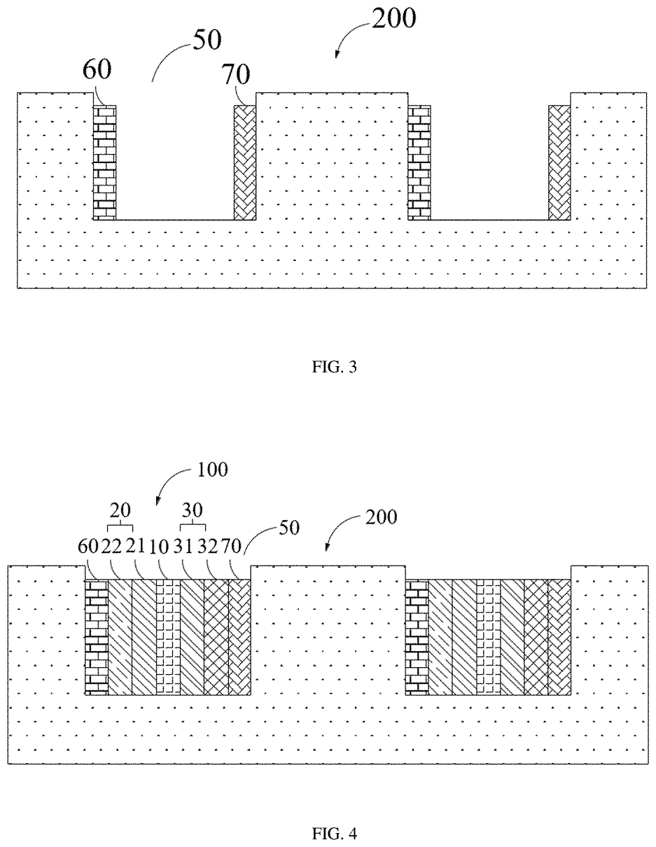

Referring to FIG. 1, FIG. 1 is a flow chart illustrating a method for light-emitting element transferring provided in an implementation of the disclosure. FIG. 2 is a schematic cross-sectional diagram illustrating a light-emitting element 100 provided in an implementation of the disclosure. FIG. 3 is a schematic cross-sectional diagram illustrating a display backplane 200 provided in an implementation of the disclosure. FIG. 4 is a schematic cross-sectional diagram illustrating a light-emitting element 100 and a display backplane 200 after the light-emitting element 100 is embedded into the display backplane 200 provided in an implementation of the disclosure. As illustrated in FIG. 1, the method for light-emitting element transferring includes the following.

S101, multiple light-emitting elements 100 illustrated in FIG. 2 are provided. Each of the multiple light-emitting elements 100 includes a substrate 10, a first light-emitting unit 20 disposed on a first side of the substrate 10, and a second light-emitting unit 30 disposed on a second side of the substrate 10. The first side of the substrate 10 is opposite to the second side of the substrate 10. The first light-emitting unit 20 includes a first epitaxial structure 21 and a first electrode group 22 that are sequentially stacked on the first side of the substrate 10. The second light-emitting unit 30 includes a second epitaxial structure 31 and a second electrode group 32 that are sequentially stacked on the second side of the substrate 10. A light-emitting color of the first light-emitting unit 20 is different from that of the second light-emitting unit 30.

S102, a display backplane 200 illustrated in FIG. 3 is provided, where multiple grooves 50 are defined on a side of the display backplane 200, a first pad group 60 for bonding with the first electrode group 22 and a second pad group 70 for bonding with the second electrode group 32 are provided on side walls of each of the multiple grooves 50.

S103, the multiple light-emitting elements 100 are embedded into the multiple grooves 50 in one-to-one correspondence, where the first electrode group 22 is bonded with the first pad group 60, and the second electrode group 32 is bonded with the second pad group 70, as illustrated in FIG. 4.

The light-emitting element 100 can simultaneously emit a blue light and a red light, a green light and a red light, or a blue light and a green light.

A shape of the groove 50 may be in a shape of square, circle, diamond, polygon, etc., which will not be limited herein.

According to the method for light-emitting element transferring provided in the implementation of the disclosure, the light-emitting element 100 capable of emitting dual-color lights can be transferred onto the display backplane 200, so that full-color display can be realized through only two times of transferring of the light-emitting elements 100, which can reduce transferring the number of times and improve efficiency and a yield of transferring.

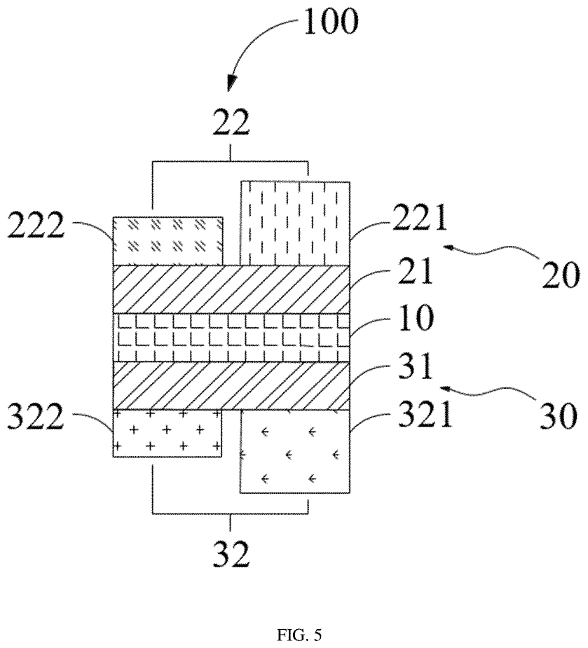

Referring to FIG. 5, FIG. 5 is a schematic cross-sectional diagram illustrating a light-emitting element 100 provided in another implementation of the disclosure. As illustrated in FIG. 5, the first electrode group 22 of the light-emitting element 100 includes a first sub-electrode 221 and a second sub-electrode 222 spaced apart from one another. The second electrode group 32 of the light-emitting element 100 includes a third sub-electrode 321 and a fourth sub-electrode 322 spaced apart from one another. The first sub-electrode 221 projects from a side of the second sub-electrode 222 away from the substrate 10, and the third sub-electrode 321 projects from a side of the fourth sub-electrode 322 away from the substrate 10.

The first sub-electrode 221 is an n-type electrode, and the second sub-electrode 222 is a p-type electrode. Alternatively, the first sub-electrode 221 is a p-type electrode, and the second sub-electrode 222 is an n-type electrode.

The third sub-electrode 321 is an n-type electrode, and the fourth sub-electrode 322 is a p-type electrode. Alternatively, the third sub-electrode 321 is a p-type electrode, and the fourth sub-electrode 322 is an n-type electrode.

Each of the first sub-electrode 221, the second sub-electrode 222, the third sub-electrode 321, and the fourth sub-electrode 322 may be made of a metal material, such as Au, Sn, In, Pt, Cu, or alloys thereof, or can also be made of a transparent conductive material, such as indium tin oxide (ITO), aluminum doped zinc oxide (AZO), a mixture of strontium vanadate and calcium vanadate, etc.

By setting the first sub-electrode 221 to project from the side of the second sub-electrode 222 away from the substrate 10 and setting the third sub-electrode 321 to project from the side of the fourth sub-electrode 322 away from the substrate 10, the light-emitting element 100 is stepped, which is conducive to alignment of the light-emitting element 100 and the display backplane 200 during transferring, so that transfer accuracy can be improved.

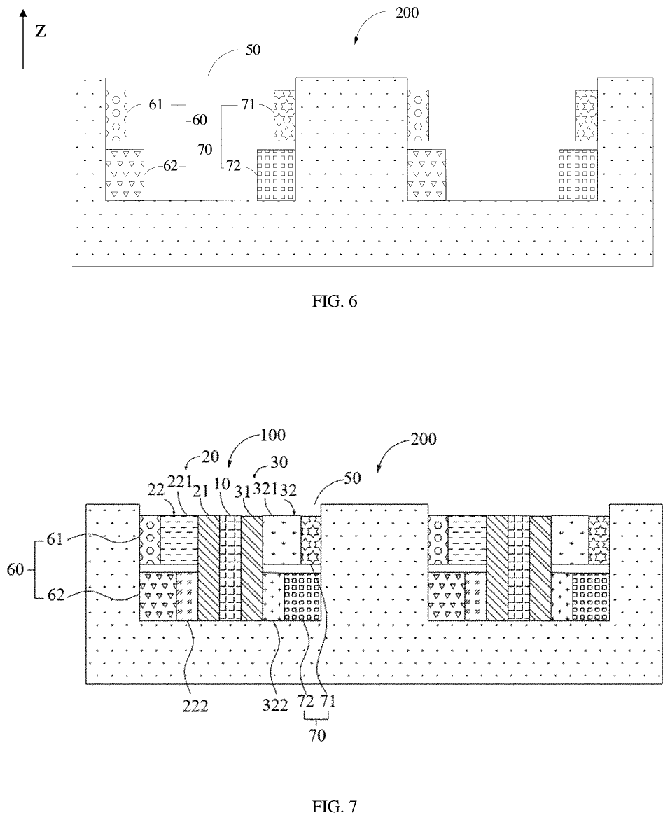

Referring to FIG. 6, FIG. 6 is a schematic cross-sectional diagram illustrating a display backplane 200 provided in another implementation of the disclosure. As illustrated in FIG. 6, the first pad group 60 of the display backplane 200 includes a first sub-pad 61 and a second sub-pad 62 spaced apart from one another. The second pad group 70 of the display backplane 200 includes a third sub-pad 71 and a fourth sub-pad 72 spaced apart from one another. The first sub-pad 61 is disposed opposite to the third sub-pad 71, and the second sub-pad 62 is disposed opposite to the fourth sub-pad 72. A gap spaced by the first sub-pad 61 and the third sub-pad 71 is greater than a gap spaced by the second sub-pad 62 and the fourth sub-pad 72. On condition that the light-emitting element 100 is embedded into the groove 50, as illustrated in FIG. 7, the first sub-electrode 221 is bonded with the first sub-pad 61, the second sub-electrode 222 is bonded with the second sub-pad 62, the third sub-electrode 321 is bonded with the third sub-pad 71, and the fourth sub-electrode 322 is bonded with the fourth sub-pad 72.

Each of the first sub-pad 61, the second sub-pad 62, the third sub-pad 71, and the fourth sub-pad 72 may be made of a metal material, such as Au, Sn, In, Pt, Cu, or alloys thereof.

In the disclosure, by setting the gap spaced by the first sub-pad 61 and the third sub-pad 71 to be greater than the gap spaced by the second sub-pad 62 and the fourth sub-pad 72, the second sub-pad 62 projects from the first sub-pad 61 and the second sub-pad 62 and the first sub-pad 61 are arranged in a stepped manner, the fourth sub-pad 72 projects from the third sub-pad 71 and the fourth sub-pad 72 and the third sub-pad 71 are arranged in a stepped manner. As such, when the stepped light-emitting element 100 is transferred onto the display backplane 200, the light-emitting element 100 can be accurately embedded into the groove 50, which is conducive to aligning and bonding the electrode groups of the light-emitting element 100 with the pad groups.

As illustrated in FIG. 6, in some implementations, a thickness of the first sub-pad 61 is less than a thickness of the second sub-pad 62, and a thickness of the third sub-pad 71 is less than a thickness of the fourth sub-pad 72, such that the gap spaced by the first sub-pad 61 and the third sub-pad 71 is greater than the gap spaced by the second sub-pad 62 and the fourth sub-pad 72. The thickness of the first sub-pad 61 is a size of the first sub-pad 61 in a direction perpendicular to a spacing direction (i.e., direction z), the thickness of the second sub-pad 62 is a size of the second sub-pad 62 in the direction perpendicular to the spacing direction, the thickness of the third sub-pad 71 is a size of the third sub-pad 71 in the direction perpendicular to the spacing direction, and the thickness of the fourth sub-pad 72 is a size of the fourth sub-pad 72 in the direction perpendicular to the spacing direction, where the spacing direction is a direction of a gap spaced by the first sub-pad 61 and the second sub-pad 62.

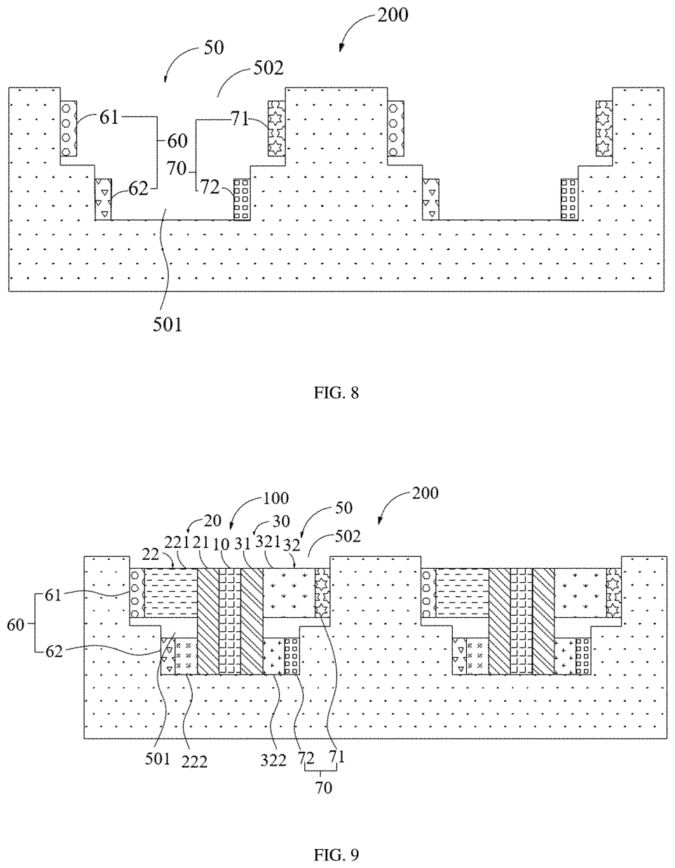

Referring to FIG. 8, FIG. 8 is a schematic cross-sectional diagram illustrating a display backplane 200 provided in yet another implementation of the disclosure. As illustrated in FIG. 8, the groove 50 of the display backplane 200 is stepped and includes a first groove 501 and a second groove 502 that are sequentially stacked on the display backplane 200. An opening area of the first groove 501 is less than that of the second groove 502. The first sub-pad 61 and the third sub-pad 71 are disposed on side walls of the second groove 502. The second sub-pad 62 and the fourth sub-pad 72 are disposed on side walls of the first groove 501.

The first sub-pad 61 and the third sub-pad 71 are disposed on the side walls of the second groove 502, and the second sub-pad 62 and the fourth sub-pad 72 are disposed on the side walls of the first groove 501. When the light-emitting element 100 is embedded into the groove 50, as illustrated in FIG. 9, the first sub-electrode 221 is bonded with the first sub-pad 61, the second sub-electrode 222 is bonded with the second sub-pad 62, the third sub-electrode 321 is bonded with the third sub-pad 71, and the fourth sub-electrode 322 is bonded with the fourth sub-pad 72.

In the disclosure, by setting the groove 50 to be stepped, it is conducive to accurately embedding the stepped light-emitting element 100 into the groove 50.

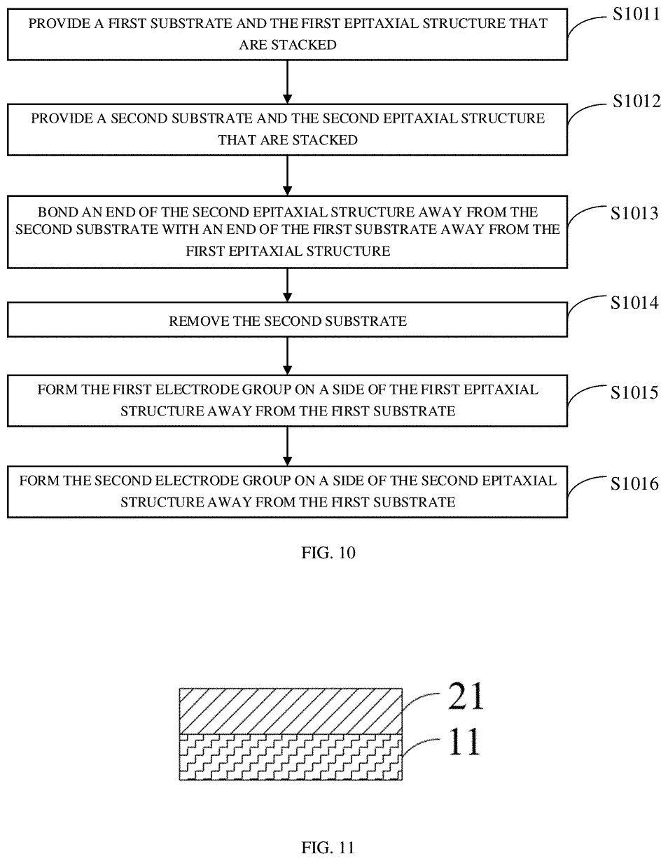

Referring to FIG. 10 to FIG. 16, FIG. 10 is a flow chart illustrating a manufacturing method of a light-emitting element 100 provided in an implementation of the disclosure, and FIG. 11 to FIG. 16 are schematic cross-sectional diagrams illustrating a light-emitting element 100 obtained after corresponding operations in FIG. 10 are completed. As illustrated in FIG. 10, in this implementation, the manufacturing method of the light-emitting element 100 includes the following.

S1011, a first substrate 11 and the first epitaxial structure 21 that are stacked are provided, as illustrated in FIG. 11.

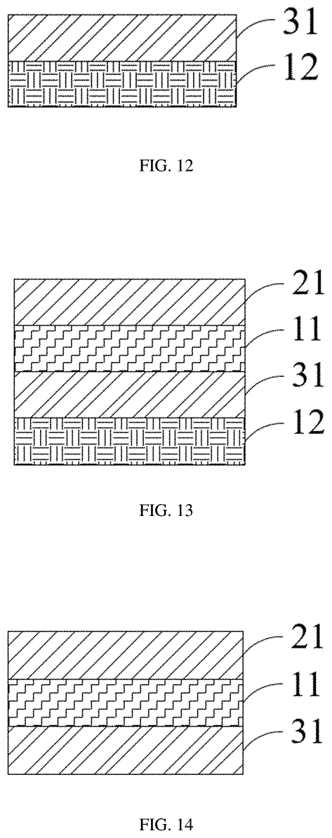

S1012, a second substrate 12 and the second epitaxial structure 31 that are stacked are provided, as illustrated in FIG. 12.

S1013, an end of the second epitaxial structure 31 away from the second substrate 12 is bonded with an end of the first substrate 11 away from the first epitaxial structure 21, as illustrated in FIG. 13.

S1014, the second substrate 12 is removed, as illustrated in FIG. 14.

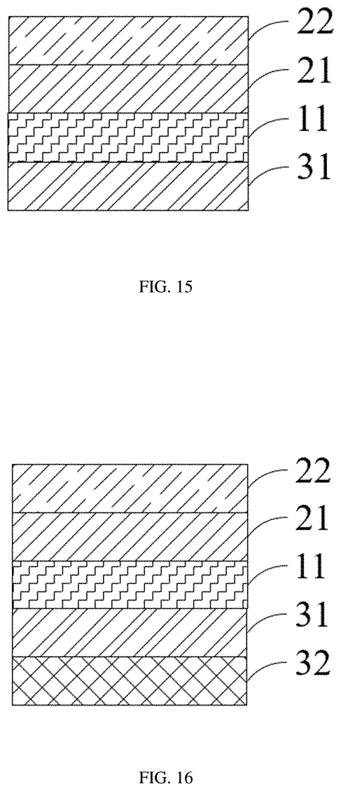

S1015, the first electrode group 22 is formed on a side of the first epitaxial structure 21 away from the first substrate 11, as illustrated in FIG. 15.

S1016, the second electrode group 32 is formed on a side of the second epitaxial structure 31 away from the first substrate 11, as illustrated in FIG. 16.

Each of the first substrate 11 and the second substrate 12 may be made of at least one of sapphire, silicon, gallium nitride, gallium arsenide, silicon carbide, zinc oxide, zinc germanide, etc. The first substrate 11 is used to provide a support for the first epitaxial structure 21 and the first electrode group 22, and the second substrate 12 is used to provide a support for the second epitaxial structure 31. In this implementation, the first substrate 11 is the foregoing substrate 10.

In some implementations, the first substrate 11 and the first epitaxial structure 21 that are stacked are provided as follows. The first epitaxial structure 21 is formed on the first substrate 11. The first epitaxial structure 21 is formed as follows. A first n-type semiconductor layer, a first light-emitting layer, and a first p-type semiconductor layer are sequentially stacked on the first substrate 11. The second substrate 12 and the second epitaxial structure 31 that are stacked are provided as follows. The second epitaxial structure 31 is formed on the second substrate 12. The second epitaxial structure 31 is formed as follows. A second n-type semiconductor layer, a second light-emitting layer, and a second p-type semiconductor layer are sequentially stacked on the second substrate 12. Each of the first n-type semiconductor layer, the first light-emitting layer, the first p-type semiconductor layer, the second n-type semiconductor layer, the second light-emitting layer, and the second p-type semiconductor layer can be formed through a thin film deposition process such as metal organic chemical vapor deposition (MOCVD), or plasma enhanced chemical vapor deposition (PECVD).

The first n-type semiconductor layer provides electrons, the first p-type semiconductor layer provides holes, and the electrons and the holes radiatively recombine in the first light-emitting layer. The first light-emitting layer may be a first multiple-quantum-well active layer, where the first multiple-quantum-well active layer includes at least one first well layer and at least one first barrier layer, and the first barrier layer and the first well layer are alternately stacked on a side of the first n-type semiconductor layer away from the first substrate 11. The first multiple-quantum-well active layer is formed as the first light-emitting layer, which can increase a radiative recombination rate of the electrons and the holes, thereby increasing light-emitting efficiency. The second p-type semiconductor layer provides holes, and electrons and the holes radiatively recombine in the second light-emitting layer to emit lights. The second light-emitting layer may be a second multiple-quantum-well active layer, where the second multiple-quantum-well active layer includes at least one second well layer and at least one second barrier layer, and the second barrier layer and the second well layer are alternately stacked on a side of the second n-type semiconductor layer away from the second substrate 12.

In some implementations, the first n-type semiconductor layer is an n-type GaN layer, and the first p-type semiconductor layer is a p-type GaN layer. The first barrier layer of the first multiple-quantum-well active layer is an InₘGa₁₋ₘN layer, and the first well layer of the first multiple-quantum-well active layer is a GaN layer, such that the first light-emitting layer emits a blue light. The second n-type semiconductor layer is an n-type (Alₓ₁Ga₁₋ₓ₁)_{1-y1}In_{y1}P layer, and the second p-type semiconductor layer is a p-type GaN layer. The second barrier layer of the second multiple-quantum-well active layer is a (Alₓ₂Ga₁₋ₓ₂)_{1-y2}In_{y2}P layer, and the second well layer of the second multiple-quantum-well active layer is a (Alₓ₃Ga₁₋ₓ₃)_{1-y3}In_{y3}P layer, such that the second light-emitting layer emits a red light. Alternatively, the second n-type semiconductor layer is an n-type GaAs layer, the second p-type semiconductor layer is a p-type GaAs layer, the second barrier layer of the second multiple-quantum-well active layer is a GaAsP layer, and the second well layer of the second multiple-quantum-well active layer is a GaAs layer, such that the second light-emitting layer emits a red light. By forming the first epitaxial structure 21 emitting a blue light and the second epitaxial structure 31 emitting a red light, the light-emitting element 100 can emit a blue light and a red light. Obviously, in other implementations, the second n-type semiconductor layer is an n-type GaN layer, the second p-type semiconductor layer is a p-type GaN layer, the second barrier layer of the second multiple-quantum-well active layer is an InₘGa₁₋ₘN layer, and the second well layer of the second multiple-quantum-well active layer is a GaN layer. The first n-type semiconductor layer is an n-type (Alₓ₁Ga₁₋ₓ₁)_{1-y1}In_{y1}P layer, the first p-type semiconductor layer is a p-type GaN layer, the first barrier layer of the first multiple-quantum-well active layer is a (Alₓ₂Ga₁₋ₓ₂)_{1-y2}In_{y2}P layer, and the first well layer of the first multiple-quantum-well active layer is a (Alₓ₃Ga₁₋ₓ₃)_{1-y3}In_{y3}P layer. Alternatively, the first n-type semiconductor layer is an n-type GaAs layer, the first p-type semiconductor layer is a p-type GaAs layer, the first barrier layer of the first multiple-quantum-well active layer is a GaAsP layer, and the first well layer of the first multiple-quantum-well active layer is a GaAs layer.

In some implementations, the first n-type semiconductor layer is an n-type GaN layer, and the first p-type semiconductor layer is a p-type GaN layer. The first barrier layer of the first multiple-quantum-well active layer is an InₙGa₁₋ₙN layer, and the first well layer of the first multiple-quantum-well active layer is a GaN layer, such that the first light-emitting layer emits a green light. The second n-type semiconductor layer is an n-type (Alₓ₁Ga₁₋ₓ₁)_{1-y1}In_{y1}P layer, and the second p-type semiconductor layer is a p-type GaN layer. The second barrier layer of the second multiple-quantum-well active layer is a (Alₓ₂Ga₁₋ₓ₂)_{1-y2}In_{y2}P layer, and the second well layer of the second multiple-quantum-well active layer is a (Alₓ₃Ga₁₋ₓ₃)_{1-y3}In_{y3}P layer, such that the second light-emitting layer emits a red light. Alternatively, the second n-type semiconductor layer is an n-type GaAs layer, the second p-type semiconductor layer is a p-type GaAs layer, the second barrier layer of the second multiple-quantum-well active layer is a GaAsP layer, and the second well layer of the second multiple-quantum-well active layer is a GaAs layer, such that the second light-emitting layer emits a red light. By forming the first epitaxial structure 21 emitting a green light and the second epitaxial structure 31 emitting a red light, the light-emitting element 100 can emit a green light and a red light. Obviously, in other implementations, the second n-type semiconductor layer is an n-type GaN layer, the second p-type semiconductor layer is a p-type GaN layer, the second barrier layer of the second multiple-quantum-well active layer is an InₙGa₁₋ₙN layer, and the second well layer of the second multiple-quantum-well active layer is a GaN layer. The first n-type semiconductor layer is an n-type (Alₓ₁Ga₁₋ₓ₁)_{1-y1}In_{y1}P layer, the first p-type semiconductor layer is a p-type GaN layer, the first barrier layer of the first multiple-quantum-well active layer is a (Alₓ₂Ga₁₋ₓ₂)_{1-y2}In_{y2}P layer, and the first well layer of the first multiple-quantum-well active layer is a (Alₓ₃Ga₁₋ₓ₃)_{1-y3}In_{y3}P layer. Alternatively, the first n-type semiconductor layer is an n-type GaAs layer, the first p-type semiconductor layer is a p-type GaAs layer, the first barrier layer of the first multiple-quantum-well active layer is a GaAsP layer, and the first well layer of the first multiple-quantum-well active layer is a GaAs layer.

In some other implementations, the first n-type semiconductor layer is an n-type GaN layer, and the first p-type semiconductor layer is a p-type GaN layer. The first barrier layer of the first multiple-quantum-well active layer is an InₘGa₁₋ₘN layer, and the first well layer of the first multiple-quantum-well active layer is a GaN layer, such that the first light-emitting layer emits a blue light. The second n-type semiconductor layer is an n-type GaN layer, and the second p-type semiconductor layer is a p-type GaN layer. The second barrier layer of the second multiple-quantum-well active layer is an InₙGa₁₋ₙN layer, and the second well layer of the second multiple-quantum-well active layer is a GaN layer, such that the second light-emitting layer emits a green light. By forming the first epitaxial structure 21 emitting a blue light and the second epitaxial structure 31 emitting a green light, the light-emitting element 100 can emit a green light and a blue light. Obviously, in other implementations, the first n-type semiconductor layer is an n-type GaN layer, the first p-type semiconductor layer is a p-type GaN layer, the first barrier layer of the first multiple-quantum-well active layer is an InₙGa₁₋ₙN layer, and the first well layer of the first multiple-quantum-well active layer is a GaN layer. The second n-type semiconductor layer is an n-type GaN layer, the second p-type semiconductor layer is a p-type GaN layer, the second barrier layer of the second multiple-quantum-well active layer is an InₘGa₁₋ₘN layer, and the second well layer of the second multiple-quantum-well active layer is a GaN layer.

In some implementations, the end of the second epitaxial structure 31 away from the second substrate 12 is bonded with the end of the first substrate 11 away from the first epitaxial structure 21 as follows. The second epitaxial structure 31 is bonded with a side of the first substrate 11 away from the first epitaxial structure 21 through a bonding process. Specifically, a metal (e.g., Au, In, Sn, Cu, or Ni) is evaporated on the end of the second epitaxial structure 31 away from the second substrate 12 and the end of the first substrate 11 away from the first epitaxial structure 21. The end of the second epitaxial structure 31 away from the second substrate 12 is attached to the end of the first substrate 11 away from the first epitaxial structure 21. By controlling a bonding temperature, e.g., 600° C.-800° C., a bonding metal on the second epitaxial structure 31 and a metal on the first substrate 11 are melted and bonded, such that the second epitaxial structure 31 is bonded with the end of the first substrate 11 away from the first epitaxial structure 21.

In some implementations, the second substrate 12 and the second epitaxial structure 31 that are stacked are provided as follows. The second substrate 12 is provided. A sacrificial layer is formed on the second substrate 12. The second epitaxial structure 31 is formed on a side of the sacrificial layer away from the second substrate 12. The sacrificial layer may be a gallium nitride layer.

In some implementations, the second substrate 12 is removed through laser lift off (LLO). Specifically, the second substrate 12 is irradiated with a laser from a side of the second substrate 12 away from the second epitaxial structure 31. Since a band gap of the second substrate 12 is far greater than a band gap of the second n-type semiconductor layer of the second epitaxial structure 31, when the second substrate 12 is irradiated with a laser, having energy between the above two band gaps, from a side of the second substrate 12 away from the second n-type semiconductor layer, the laser can pass through the second substrate 12 and can be absorbed by the second n-type semiconductor layer, such that part of the second n-type semiconductor layer is thermally decomposed, and thus the second substrate 12 is separated from the second epitaxial structure 31.

In other implementations, the sacrificial layer is formed between the second substrate 12 and the second epitaxial structure 31, and a band gap of the sacrificial layer is less than the band gap of the second substrate 12. When the second substrate 12 is irradiated with a laser, having energy between the band gap of the sacrificial layer and the band gap of the substrate, from a side of the second substrate 12 away from the sacrificial layer, the laser can pass through the second substrate 12 and can be absorbed by the sacrificial layer, such that the sacrificial layer is thermally decomposed, and thus the second substrate 12 is separated from the second epitaxial structure 31.

In some implementations, the first electrode group 22 is formed on the side of the first epitaxial structure 21 away from the first substrate 11 as follows. The first sub-electrode 221 and the second sub-electrode 222 arranged at intervals are formed on the side of the first epitaxial structure 21 away from the first substrate 11. The first sub-electrode 221 and the second sub-electrode 222 arranged at intervals are formed on the side of the first epitaxial structure 21 away from the first substrate 11 through evaporation, magnetron sputtering, or other processes. The first electrode group 22 is used to bond with the first pad group 60, such that the first epitaxial structure 21 is connected with the display backplane 200, and thus the first epitaxial structure 21 can be controlled to emit lights by electrifying the display backplane 200.

In some implementations, the second electrode group 32 is formed on the side of the second epitaxial structure 31 away from the first substrate 11 as follows. The third sub-electrode 321 and the fourth sub-electrode 322 arranged at intervals are formed on the side of the second epitaxial structure 31 away from the first substrate 11. The third sub-electrode 321 and the fourth sub-electrode 322 arranged at intervals are formed on the side of the second epitaxial structure 31 away from the first substrate 11 through evaporation, magnetron sputtering, or other processes. The second electrode group 32 is used to bond with the second pad group 70, such that the second epitaxial structure 31 is connected with the display backplane 200, and thus the second epitaxial structure 31 can be controlled to emit lights by electrifying the display backplane 200.

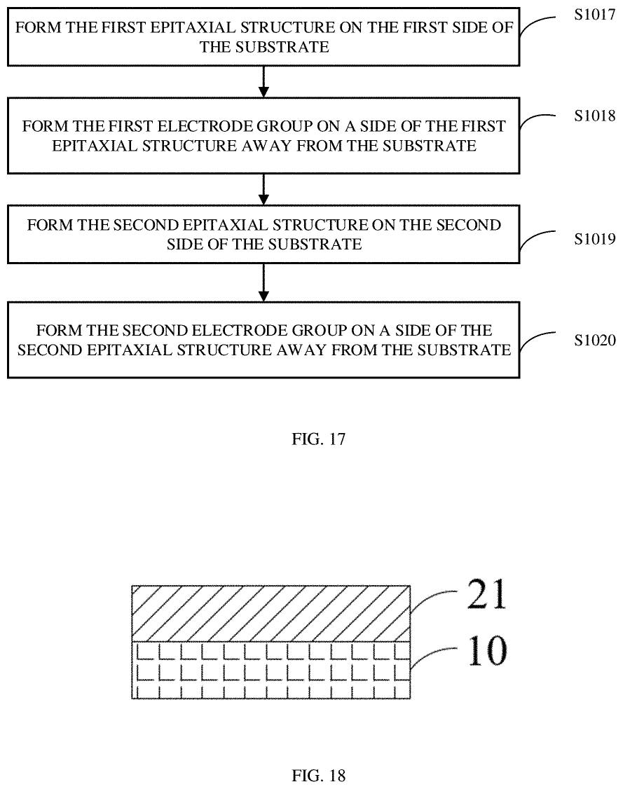

Referring to FIG. 17 to FIG. 21, FIG. 17 is a flow chart illustrating a manufacturing method of a light-emitting element 100 provided in another implementation of the disclosure. FIG. 18 to FIG. 21 are schematic cross-sectional diagrams illustrating a light-emitting element 100 obtained after corresponding operations in FIG. 17 are completed. As illustrated in FIG. 17, in this implementation, the manufacturing method of the light-emitting element 100 includes the following.

S1017, the first epitaxial structure 21 is formed on the first side of the substrate 10, as illustrated in FIG. 18.

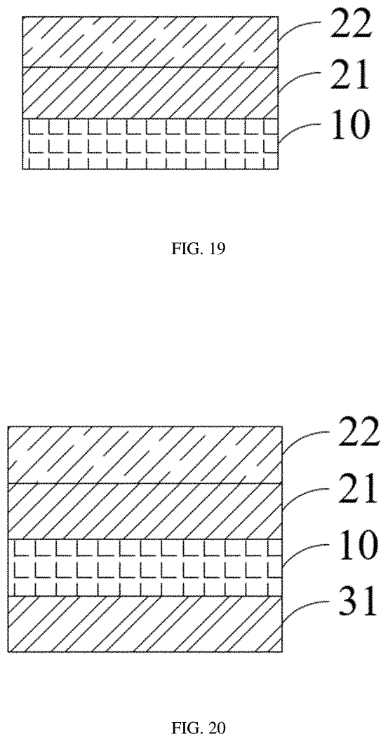

S1018, the first electrode group 22 is formed on a side of the first epitaxial structure 21 away from the substrate 10, as illustrated in FIG. 19.

S1019, the second epitaxial structure 31 is formed on the second side of the substrate 10, as illustrated in FIG. 20.

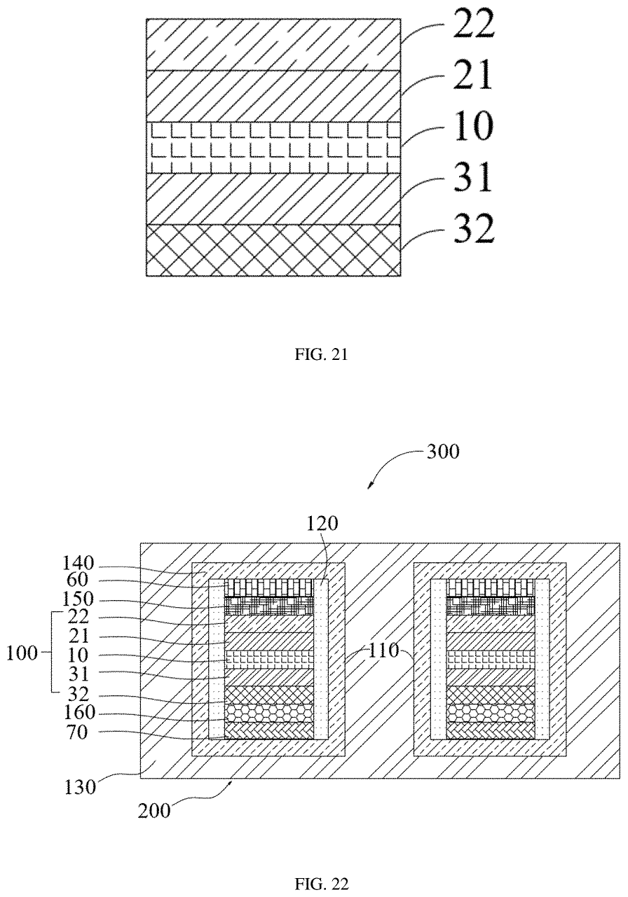

S1020, the second electrode group 32 is formed on a side of the second epitaxial structure 31 away from the substrate 10, as illustrated in FIG. 21.

The substrate 10 may be made of at least one of sapphire, silicon, gallium nitride, gallium arsenide, silicon carbide, zinc oxide, zinc germanide, etc. The substrate 10 is used to provide a support for other film layers.

In some implementations, the first epitaxial structure 21 is formed on the first side of the substrate 10 as follows. A third n-type semiconductor layer, a third light-emitting layer, and a third p-type semiconductor layer are sequentially stacked on the first side of the substrate 10. The third light-emitting layer may be a third multiple-quantum-well active layer, where the third multiple-quantum-well active layer includes at least one third well layer and at least one third barrier layer, and the third barrier layer and the third well layer are alternately stacked on a side of the third n-type semiconductor layer away from the substrate 10. The third n-type semiconductor layer may be an n-type GaN layer, the third p-type semiconductor layer may be a p-type GaN layer, the third barrier layer may be an InₘGa₁₋ₘN layer, and the third well layer may be a GaN layer, such that the third light-emitting layer can emit a blue light.

In some implementations, the second epitaxial structure 31 is formed on the second side of the substrate 10 as follows. A fourth n-type semiconductor layer, a fourth light-emitting layer, and a fourth p-type semiconductor layer are sequentially stacked on the second side of the substrate 10. The fourth light-emitting layer may be a fourth multiple-quantum-well active layer, where the fourth multiple-quantum-well active layer includes at least one fourth well layer and at least one fourth barrier layer, and the fourth barrier layer and the fourth well layer are alternately stacked on a side of the fourth n-type semiconductor layer away from the substrate 10. The fourth n-type semiconductor layer may be an n-type GaN layer, the fourth p-type semiconductor layer may be a p-type GaN layer, the fourth barrier layer may be an InₙGa₁₋ₙN layer, and the fourth well layer may be a GaN layer, such that the fourth light-emitting layer can emit a green light.

According to the manufacturing method of the light-emitting element 100 provided in the disclosure, different epitaxial structures are formed on the first substrate 11 and the second substrate 12 respectively, and the epitaxial structure on the second substrate 12 is bonded with the first substrate 11. As such, the light-emitting element 100 formed can simultaneously emit two different colors of lights, and a full-color display screen can be obtained through only two times of transferring of the light-emitting elements 100, while in the related art, the full-color display screen is obtained through at least three times of transferring of single-color light-emitting elements, thereby increasing efficiency and a yield of mass transfer.

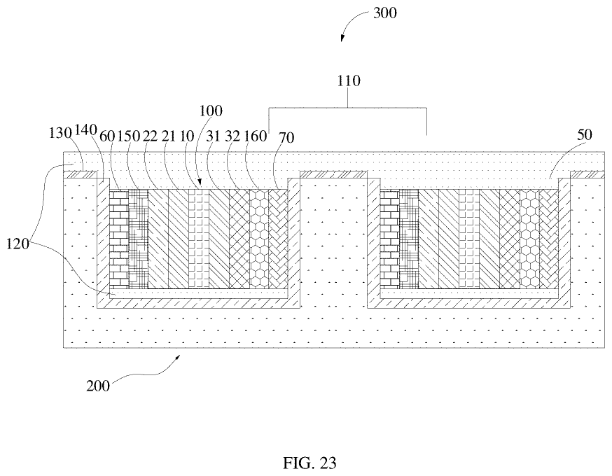

Referring to FIG. 22 and FIG. 23, FIG. 22 is a top view illustrating a display panel 300 provided in an implementation of the disclosure, and FIG. 23 is a side view illustrating a display panel 300 provided in an implementation of the disclosure. As illustrated in FIG. 22 and FIG. 23, the display panel 300 includes a display backplane 200 and multiple pixel units 110 fixed on the display backplane 200. Each of the multiple pixel units 110 includes two light-emitting elements 100 spaced apart from one another, and the light-emitting element 100 is fixed onto the display backplane 200 with the method for light-emitting element transferring provided in any of the foregoing implementations.

The pixel unit 110 of the above display panel 300 includes the light-emitting elements 100 capable of emitting dual-color lights, and the display panel 300 can realize full-color display through only two times of transferring of the light-emitting elements 100, so that the number of times of the transferring can be reduced, production efficiency of the display panel 300 can be improved, and a production cost of the display panel 300 can be reduced.

In some implementations, the two light-emitting elements 100 in each of the multiple pixel units 110 are a first light-emitting element and a second light-emitting element. A first light-emitting unit 20 of the first light-emitting element is configured to emit a red light, and a second light-emitting unit 30 of the first light-emitting element is configured to emit a blue light, such that the first light-emitting element can simultaneously emit a red light and a blue light. A first light-emitting unit 20 of the second light-emitting element is configured to emit a red light, and a second light-emitting unit 30 of the second light-emitting element is configured to emit a green light, such that the second light-emitting element can simultaneously emit a red light and a green light.

In the disclosure, by providing in each pixel unit 110 the two light-emitting elements 100 each capable of emitting a red light, each pixel unit 110 includes red-green-blue-red (RGBR) four sub-pixels. Compared to RGB three sub-pixels in the existing pixel unit, each pixel unit 110 of the display panel 300 of the disclosure includes two R sub-pixels, which can solve a problem of low light-emitting efficiency of a red light, thereby significantly improving brightness of the display panel 300.

Referring to FIG. 22 and FIG. 23 again, in some implementations, the display panel 300 further includes an encapsulation layer 120, where the encapsulation layer 120 is filled in a gap spaced by the groove 50 and the light-emitting element 100 and covered on the light-emitting element 100.

A thickness of the encapsulation layer 120 may be greater than or equal to 100 μm, to protect the light-emitting element 100 from being scratching. The thickness of the encapsulation layer 120 is a size of the encapsulation layer 120 in a direction perpendicular to the display backplane 200.

The encapsulation layer 120 may be made of an encapsulant, e.g., epoxy resin or organic silicone resin. A transmittance of the encapsulant is greater than 70%, which can reduce brightness loss of the display panel 300.

In some implementations, the encapsulation layer 120 is further covered on a surface of the display backplane 200 where the groove 50 is defined, to further fix the light-emitting element 100 onto the display backplane 200.

In some implementations, the encapsulant can be injected into the groove 50 through an injection molding process. Specifically, the display panel 300 is placed into an injection mold, where the injection mold includes an upper mold, a lower mold, and a drive apparatus. A mold cavity and a glue flowing passage communicating with the mold cavity are defined in the lower mold, the display panel 300 is in the mold cavity of the lower mold, and the drive apparatus is configured to drive the upper mold and the lower mold to be closed. By injecting the encapsulant into the mold cavity through the glue flowing passage, the encapsulant is filled into the gap spaced by the groove 50 and the light-emitting element 100 and covered on surfaces of the light-emitting element 100 and the display backplane 200, to form the encapsulation layer 120.

Furthermore, in some implementations, a diffusion particle-based lamination transfer process is performed on a surface of the encapsulation layer 120, to form a pattern on the surface of the encapsulation layer 120, such that degree of scattering of lights emitted by the light-emitting element 100 can be increased and a viewing angle of the display panel 300 can be widened.

Referring to FIG. 22 and FIG. 23 again, in some implementations, the display panel 300 further includes a blackening layer 130, where the blackening layer 130 is covered on a region of the display backplane 200 other than the multiple grooves 50.

A thickness of the blackening layer 130 may range from 20 μm to 40 μm. Exemplarily, the thickness of the blackening layer 130 is 30 μm. The blackening layer 130 may be made of a black ink. The thickness of the blackening layer 130 is a size of the blackening layer 130 in a direction perpendicular to a surface of the display backplane 200 where the blackening layer 130 is disposed.

In some implementations, the blackening layer 130 can be coated on the region of the display backplane 200 other than the multiple grooves 50 through an inkjet manner with a stencil. Specifically, a mesh opening of the stencil is aligned with the region of the display backplane 200 other than the multiple grooves 50, and the blackening layer 130 is formed on the region of the display backplane 200 other than the multiple grooves 50 by performing inkjet printing.

If the display panel 300 includes the encapsulation layer 120, the blackening layer 130 is arranged between the display backplane 200 and the encapsulation layer 120, so that the encapsulation layer 120 can protect the blackening layer 130 from being damaged, and the blackening layer 130 is not easy to fall off.

Referring to FIG. 22 and FIG. 23 again, in some implementations, the display panel 300 further includes a reflective layer 140 stacked on walls of the groove 50. The reflective layer 140 is disposed between the walls of the groove 50 and the light-emitting element 100. The reflective layer 140 is configured to reflect a light, which is emitted to the groove 50 from the light-emitting element 100, to an opening of the groove 50, which can effectively improve light utilization efficiency and prevent color impurity of a displayed image caused by cross color due to a light, which is emitted from a side surface of the light-emitting element 100, entering an adjacent light-emitting element 100. The side surface of the light-emitting element 100 is a surface perpendicular to a top surface of the light-emitting element 100, and the top surface of the light-emitting element 100 is a surface of the light-emitting element 100 exposed from the groove 50.

The reflective layer 140 may be a silver coating. In some implementations, the silver coating includes a polyester layer, a silver layer, and a polyester layer that are sequentially stacked.

If the display panel 300 includes the encapsulation layer 120, the encapsulation layer 120 is filled in a gap spaced by the reflective layer 140 and the light-emitting element 100 and covered on the light-emitting element 100.

Referring to FIG. 22 and FIG. 23 again, in some implementations, the display panel 300 further includes a first bonding layer 150 and a second bonding layer 160. The first bonding layer 150 is disposed between the first electrode group 22 and the first pad group 60 to bond the first electrode group 22 with the first pad group 60. The second bonding layer 160 is disposed between the second electrode group 32 and the second pad group 70 to bond the second electrode group 32 with the second pad group 70.

The bonding layer 160 may be made of a metal material with a low melting point, e.g., an alloy of Au and Sn, In, indium stannide, etc. The bonding layer 160 can also be made of an anisotropic conductive adhesive.

It is to be noted that, for the sake of simplicity, the foregoing method implementations are described as a series of action combinations. However, it will be appreciated by those skilled in the art that the disclosure is not limited by the sequence of actions described. According to the disclosure, some steps may be performed in other orders or simultaneously.

In the foregoing implementations, the description of each implementation has its own emphasis. For the parts not described in detail in one implementation, reference may be made to related descriptions in other implementations.

It is to be understood that the disclosure is not to be limited to the disclosed implementations. Those of ordinary skill in the art can make improvements or changes based on the above description, and all these improvements and changes should fall within the protection scope of the appended claims of this disclosure.

What is claimed is:

1. A method for light-emitting element transferring, comprising:
providing a plurality of light-emitting elements, wherein
each of the plurality of light-emitting elements comprises a substrate, a first light-emitting unit disposed on a first side of the substrate, and a second light-emitting unit disposed on a second side of the substrate;
the first side of the substrate is opposite to the second side of the substrate;
the first light-emitting unit comprises a first epitaxial structure and a first electrode group that are sequentially stacked on the first side of the substrate;
the second light-emitting unit comprises a second epitaxial structure and a second electrode group that are sequentially stacked on the second side of the substrate; and
a light-emitting color of the first light-emitting unit is different from that of the second light-emitting unit;
providing a display backplane, wherein a plurality of grooves are defined on a side of the display backplane, a first pad group and a second pad group are provided on side walls of each of the plurality of grooves; and
embedding the plurality of light-emitting elements into the plurality of grooves in one-to-one correspondence, wherein the first electrode group is bonded with the first pad group, and the second electrode group is bonded with the second pad group.

2. The method for light-emitting element transferring of claim 1, wherein
the first electrode group comprises a first sub-electrode and a second sub-electrode spaced apart from one another;
the second electrode group comprises a third sub-electrode and a fourth sub-electrode spaced apart from one another; and
the first sub-electrode projects from a side of the second sub-electrode away from the substrate, and the third sub-electrode projects from a side of the fourth sub-electrode away from the substrate.

3. The method for light-emitting element transferring of claim 2, wherein
the first pad group comprises a first sub-pad and a second sub-pad;
the second pad group comprises a third sub-pad and a fourth sub-pad;
the first sub-pad is disposed opposite to the third sub-pad, and the second sub-pad is disposed opposite to the fourth sub-pad;
a gap spaced by the first sub-pad and the third sub-pad is greater than a gap spaced by the second sub-pad and the fourth sub-pad; and
on condition that the light-emitting element is embedded into the groove, the first sub-electrode is bonded with the first sub-pad, the second sub-electrode is bonded with the second sub-pad, the third sub-electrode is bonded with the third sub-pad, and the fourth sub-electrode is bonded with the fourth sub-pad.

4. The method for light-emitting element transferring of claim 3, wherein
the groove comprises a first groove and a second groove that are sequentially stacked on the display backplane and stacked in a stepped manner;
the first groove has an opening area less than the second groove;
the first sub-pad and the third sub-pad are disposed on side walls of the second groove; and
the second sub-pad and the fourth sub-pad are disposed on side walls of the first groove.

5. The method for light-emitting element transferring of claim 1, wherein providing the plurality of light-emitting elements comprises:
providing a first substrate and the first epitaxial structure that are stacked;
providing a second substrate and the second epitaxial structure that are stacked;
bonding an end of the second epitaxial structure away from the second substrate with an end of the first substrate away from the first epitaxial structure;
removing the second substrate;
forming the first electrode group on a side of the first epitaxial structure away from the first substrate; and
forming the second electrode group on a side of the second epitaxial structure away from the first substrate.

6. The method for light-emitting element transferring of claim 5, wherein providing the second substrate and the second epitaxial structure that are stacked comprises:
providing the second substrate;
forming a sacrificial layer on the second substrate; and
forming the second epitaxial structure on a side of the sacrificial layer away from the second substrate.

7. The method for light-emitting element transferring of claim 1, wherein providing the plurality of light-emitting elements comprises:
forming the first epitaxial structure on the first side of the substrate;
forming the first electrode group on a side of the first epitaxial structure away from the substrate;
forming the second epitaxial structure on the second side of the substrate; and
forming the second electrode group on a side of the second epitaxial structure away from the substrate.

8. A display panel, comprising:
a display backplane; and
a plurality of pixel units fixed on the display backplane, wherein each of the plurality of pixel units comprises two light-emitting elements spaced apart from one another, and the light-emitting element is fixed onto the display backplane by embedding light-emitting elements of the plurality of pixel units into a plurality of grooves in one-to-one correspondence, wherein
each of the light-emitting elements comprises a substrate, a first light-emitting unit disposed on a first side of the substrate, and a second light-emitting unit disposed on a second side of the substrate;
the first side of the substrate is opposite to the second side of the substrate;
the first light-emitting unit comprises a first epitaxial structure and a first electrode group that are sequentially stacked on the first side of the substrate;
the second light-emitting unit comprises a second epitaxial structure and a second electrode group that are sequentially stacked on the second side of the substrate;
a light-emitting color of the first light-emitting unit is different from that of the second light-emitting unit;
the plurality of grooves are defined on a side of the display backplane, and a first pad group and a second pad group are provided on side walls of each of the plurality of grooves; and
the first electrode group is bonded with the first pad group, and the second electrode group is bonded with the second pad group.

9. The display panel of claim 8, wherein
the two light-emitting elements in each of the plurality of pixel units are a first light-emitting element and a second light-emitting element;
the first light-emitting element is configured to emit a red light and a blue light; and
the second light-emitting element is configured to emit a red light and a green light.

10. The display panel of claim 8, further comprising an encapsulation layer, wherein the encapsulation layer is filled in a gap spaced by the groove and the light-emitting element and covered on the light-emitting element.

11. The display panel of claim 8, further comprising a blackening layer, wherein the blackening layer is covered on a region of the display backplane other than the plurality of grooves.

12. The display panel of claim 8, further comprising a reflective layer stacked on walls of the groove, wherein
the reflective layer is disposed between the walls of the groove and the light-emitting element; and
the reflective layer is configured to reflect a light, which is emitted to the groove from the light-emitting element, to an opening of the groove.

13. The display panel of claim 8, further comprising a first bonding layer and a second bonding layer, wherein
the first bonding layer is disposed between the first electrode group and the first pad group to bond the first electrode group with the first pad group; and
the second bonding layer is disposed between the second electrode group and the second pad group to bond the second electrode group with the second pad group.

14. The display panel of claim 10, wherein the encapsulation layer has a thickness greater than or equal to 100 μm, and the thickness of the encapsulation layer is a size of the encapsulation layer in a direction perpendicular to the display backplane.

15. The display panel of claim 8, wherein
the first electrode group comprises a first sub-electrode and a second sub-electrode spaced apart from one another;
the second electrode group comprises a third sub-electrode and a fourth sub-electrode spaced apart from one another; and
the first sub-electrode projects from a side of the second sub-electrode away from the substrate, and the third sub-electrode projects from a side of the fourth sub-electrode away from the substrate.

16. The display panel of claim 15, wherein
the first pad group comprises a first sub-pad and a second sub-pad;
the second pad group comprises a third sub-pad and a fourth sub-pad;
the first sub-pad is disposed opposite to the third sub-pad, and the second sub-pad is disposed opposite to the fourth sub-pad;
a gap spaced by the first sub-pad and the third sub-pad is greater than a gap spaced by the second sub-pad and the fourth sub-pad; and
on condition that the light-emitting element is embedded into the groove, the first sub-electrode is bonded with the first sub-pad, the second sub-electrode is bonded with the second sub-pad, the third sub-electrode is bonded with the third sub-pad, and the fourth sub-electrode is bonded with the fourth sub-pad.

17. The display panel of claim 16, wherein
the groove comprises a first groove and a second groove that are sequentially stacked on the display backplane and stacked in a stepped manner;
the first groove has an opening area less than the second groove;
the first sub-pad and the third sub-pad are disposed on side walls of the second groove; and
the second sub-pad and the fourth sub-pad are disposed on side walls of the first groove.

18. The display panel of claim 8, wherein the light-emitting element is provided by:
providing a first substrate and the first epitaxial structure that are stacked;
providing a second substrate and the second epitaxial structure that are stacked;
bonding an end of the second epitaxial structure away from the second substrate with an end of the first substrate away from the first epitaxial structure;
removing the second substrate;
forming the first electrode group on a side of the first epitaxial structure away from the first substrate; and
forming the second electrode group on a side of the second epitaxial structure away from the first substrate.

19. The display panel of claim 18, wherein the second substrate and the second epitaxial structure are provided by:
providing the second substrate;
forming a sacrificial layer on the second substrate; and
forming the second epitaxial structure on a side of the sacrificial layer away from the second substrate.

20. The display panel of claim 8, wherein the light-emitting element is provided by:
forming the first epitaxial structure on the first side of the substrate;
forming the first electrode group on a side of the first epitaxial structure away from the substrate;
forming the second epitaxial structure on the second side of the substrate; and
forming the second electrode group on a side of the second epitaxial structure away from the substrate.
